(19) United States
(12) Patent Application Publication
(10) Pub. No.: US 2024/0431058 A1
(43) Pub. Date: Dec. 26, 2024

(54) RECORDING DEVICE, MANUFACTURING METHOD THEREFOR, AND HOUSING

(71) Applicant: NHK SPRING CO., LTD., Yokohama-shi, Kanagawa (JP)

(72) Inventors: Yoshio YAMADA, Yokohama-shi, Kanagawa (JP); Yusuke TANABE, Yokohama-shi, Kanagawa (JP); Shuji TAKAHASHI, Yokohama-shi, Kanagawa (JP)

(21) Appl. No.: 18/706,163

(22) PCT Filed: Oct. 31, 2022
(86) PCT No.: PCT/JP2022/040841

§ 371 Date: Apr. 30, 2024

(30) Foreign Application Priority Data
Nov. 8, 2021 (JP) 2021-182077

(51) Int. Cl. H05K 5/06; G11B 33/02; G11B 33/12

(52) U.S. Cl. CPC H05K 5/061; G11B 33/022; G11B 33/125

(57) ABSTRACT

A recording device comprises a base, a cover attached to the base, a gasket, a recessed portion provided on the base, wherein the gasket is provided with a tip end portion having an arc-shaped cross section in a free state, is compressed in a state that a center of the tip end portion in the free state is deviated from a center of an opening of the recessed portion in a width direction intersecting the compressing direction, and is in contact with at least one opening edge in the width direction of the recessed portion and an inner face of the recessed portion in the compressed state.

### FIELD OF THE INVENTION

The present invention relates to a recording device such as hard disk drive, a manufacturing method therefor, and a housing.

### BACKGROUND OF THE INVENTION

A hard disk drive as a recording device requires sealability so that dust, moisture and the like are not entered into a space accommodating disks as recording media.

In order to ensure the sealability, a gasket is provided in a compressed state between a base and a cover of a housing that define a space as Patent document 1, for example.

The gasket defines an inside and an outside of the housing and makes a sealability higher as a width (effective width) between the inside and the outside is larger. Accordingly, the gasket is preferably used while compressibility is raised and the effective width is increased.

Raising the compressibility of the gasket too much, repulsive force of the gasket, however, becomes larger so that the cover or the base may be deformed. Further, if the cover or the base is deformed, the compressibility of the gasket is lowered so that no increase of the effective width may be expected substantively. Furthermore, there is a limit on the compressibility of the gasket so that there is also a limit on the increase of the effective width of the gasket according to the raising of the compressibility.

Such a problem may be widely issued on a housing other than the recording device being the hard disk drive or the like, the housing in which a gasket is interposed between a base and a cover in a compressed state.
PATENT LITERATURE 1: JPH08-045264A

### SUMMARY OF THE INVENTION

A problem to be solved is that there is a limit on improvement of sealability based on increase of an effective width according to compressibility of a gasket.

The present invention provides a recording device, comprising a base for a housing accommodating a recording medium, a cover attached to the base to close a space of the housing accommodating the recording medium, a gasket attached to one of the base and the cover and being in contact with the other of the base and the cover so as to be interposed between the base and the cover in a compressed state, and a recessed portion provided on said other of the base and the cover so that part of the gasket in the compressed state is entered into the recessed portion a compressing direction. The gasket is provided with a tip end portion having an arc-shaped cross section in a free state, is compressed in a state that a center of the tip end portion in the free state is deviated from a center of an opening of the recessed portion in a width direction intersecting the compressing direction, and is in contact with at least one of opening edges in the width direction of the recessed portion and an inner face of the recessed portion in the compressed state.

Further, the present invention provides a manufacturing method for a recording device that attaches a cover to a base for a housing accommodating a recording medium to close a space of the housing accommodating the recording medium. The manufacturing method comprises facing the cover and the base mutually and bringing a tip end portion of a gasket provided on one of the cover and the base into contact with an inner face of a recessed portion provided on the other of the cover and the base, and approaching the cover and the base to each other to compress the gasket. This swells part of the gasket in a width direction intersecting a compressing direction while said part of the gasket in a compressed state is entered into the recessed portion in the compressing direction and brings the gasket into contact with at least one of opening edges in the width direction of the recessed portion to conduct the closing.

Furthermore, the present invention provides a housing comprising a base and a cover attached to the base, a gasket attached to one of the base and the cover and being in contact with the other of the base and the cover so as to be interposed between the base and the cover in a compressed state, and a recessed portion provided on said other of the base and the cover so that part of the gasket in the compressed state is entered into the recessed portion in a compressing direction. The gasket is provided with a tip end portion having an arc-shaped cross section in a free state, is compressed in a state that a center of the tip end portion in the free state is deviated from a center of an opening of the recessed portion in a width direction intersecting the compressing direction, and is in contact with at least one of opening edges in the width direction of the recessed portion and an inner face of the recessed portion in the compressed state.

The present invention increases an effective width to improve sealability while preventing repulsive force of the gasket from being raised.

### BRIEF DESCRIPTION OF THE DRAWINGS

FIG. 1 is a plan view of a recording device according to an embodiment 1 of the present invention:

FIG. 2A is a schematic sectional view taken along a line II-II of the recording device of FIG. 1, and FIG. 2B is a schematic sectional view according to a modification:

FIG. 3A is a schematic sectional view crossing a fastener and illustrating the gasket and its periphery of FIG. 1 with enlargement, and FIG. 3B is a schematic sectional view illustrating a situation before attaching the cover of the same:

FIG. 4A is a schematic sectional view not crossing the fastener and illustrating the gasket and its periphery of FIG. 1 with enlargement, and FIG. 4B is a schematic sectional view illustrating a situation before attaching the cover of the same:

FIG. 5 is an enlarged sectional view of a recessed portion illustrated in FIG. 3:

FIG. 6A is an enlarged sectional view illustrating a modification of the recessed portion, FIG. 6B is an enlarged sectional view illustrating another modification of the recessed portion, and FIG. 6C is an enlarged sectional view illustrating still another modification of the recessed portion:

FIG. 7 is a bottom view of the cover illustrated in FIG. 1:

FIG. 8 is a conceptual view illustrating the gasket illustrated in FIG. 3 in a free state and the recessed portion side by side:

FIGS. 9A-D are schematic sectional views illustrating manufacturing process for the recording device of the embodiment 1:

FIG. 10 is a schematic sectional view illustrating a gasket according to a modification of the embodiment 1 and its periphery with enlargement:

FIG. 11A is a schematic sectional view illustrating a gasket according to another modification of the embodiment 1 and its periphery with enlargement, and FIG. 11B is a schematic sectional view illustrating a situation before attaching a cover of the same:

FIG. 12A is a schematic sectional view illustrating a gasket according to another modification of the embodiment 1 and its periphery with enlargement, and FIG. 12B is a schematic sectional view illustrating a situation before attaching a cover of the same:

FIG. 13A is a schematic sectional view crossing a fastener and illustrating a gasket according to an embodiment 2 of the present invention and its periphery with enlargement, and FIG. 13B is a schematic sectional view illustrating a situation before attaching the cover of the same;

FIG. 14A is a schematic sectional view crossing a fastener and illustrating a gasket according to a modification of the embodiment 2 and its periphery with enlargement, and FIG. 14B is a schematic sectional view illustrating a situation before attaching the cover of the same:

FIG. 15 is a schematic sectional view crossing a fastener and illustrating a gasket according to another modification of the embodiment 2 and its periphery with enlargement:

FIG. 16 is a schematic sectional view crossing a fastener and illustrating a gasket according to still another modification of the embodiment 2 and its periphery with enlargement:

FIG. 17A is a schematic sectional view crossing a fastener and illustrating a gasket according to an embodiment 3 of the present invention and its periphery with enlargement, and FIG. 17B is a schematic sectional view illustrating a situation before attaching the cover of the same; and

FIGS. 18A-D are schematic sectional views illustrating manufacturing process for a recording device of the embodiment 3.

### EMBODIMENT FOR CARRYING OUT THE INVENTION

The object of increasing an effective width to improve sealability while preventing repulsive force of the gasket from being raised is accomplished by provision of a recessed portion into which part of a gasket in a compressed state is entered.

Namely, a recording device (1) is provided with a base (9) and a cover (11) for a housing (3), a gasket (21), and a recessed portion (17).

The base (9) accommodates a recording medium (5), the cover (11) is attached to the base (9) to close a space (3a) of the housing (3) accommodating the recording medium (5). The gasket (21) is attached to one of the base (9) and the cover (11) and is in contact with the other of the base (9) and the cover (11) so as to be interposed between the base (9) and the cover (11) in a compressed state. The recessed portion (17) is provided on said other of the base (9) and the cover (11) so that part of the gasket (21) in the compressed state is entered into the recessed portion in a compressing direction.

The gasket (21) is provided with a tip end portion (21b) having an arc-shaped cross section in a free state, is compressed in a state that a center (C2) of the tip end portion (21b) in the free state is deviated from a center (C1) of an opening (17d) of the recessed portion (17) in a width direction intersecting the compressing direction, and is in contact with at least one of opening edges (17e, 17f) in the width direction of the recessed portion (17) and an inner face of the recessed portion (17) in the compressed state.

The gasket (21) may be in contact with both the opening edges (17e, 17f) in the width direction of the recessed portion (17).

The gasket (21) may be in contact with a bottom portion of the inner face of the recessed portion (17).

An inside of the recessed portion (17) may be filled with the entered gasket (21).

A manufacturing method for the recording device (1) faces the cover (11) and the housing (3) mutually and brings a tip end portion (21b) of a gasket (21) provided on one of the cover (11) and the housing (3) into contact with an inner face of a recessed portion (17) provided on the other of the cover (11) and the housing (3). Next, it approaches the cover (11) and the housing (3) to each other to compress the gasket (21). This swells part of the gasket (21) in a width direction intersecting a compressing direction while said part of the gasket (21) is entered in the recessed portion (17) in the compressing direction and brings the gasket (21) in a compressed state into contact with at least one of opening edges (17e, 17f) in the width direction of the recessed portion (17) to conduct the closing.

In the manufacturing method for the recording device (1), the center (C2) of the tip end portion (21b) of the gasket (21) in the free state and the center (C1) of the opening (17d) of the recessed portion (17) may be matched with or deviated from each other in the width direction.

In any case, the tip end portion (21b) of the gasket (21) may come into contact with a bottom portion of the recessed portion (17) at the time of the facing of the cover (11) and the base (9), the gasket (21) may be in contact with both the opening edges (17e, 17f) in the width direction of the recessed portion (17) at the time of the closing, and the inside of the recessed portion (17) may be filled with the entered gasket (21).

A width (W1) of the opening (17d) of the recessed portion (17) may be greater than a corresponding width (W2) of the gasket (21) in the free state. The corresponding width (W2) is a width in the gasket (21) in the free state at an apart position apart from said one of the base (9) and the cover (11) by a distance (D2), the distance being from said one of the base (9) and the cover (11) to the opening (17d) of the recessed portion (17) in the closed state.

A volume (V2) of the gasket (21) in the free state on a tip end side from the apart position in the compressing direction may be greater than a volumetric capacity (V1) of the recessed portion (17).

A housing (3) comprises the base (9) and the cover (11), the gasket (21), and the recessed portion (17). The housing (3) may be applied as a housing other than for the recording device (1).

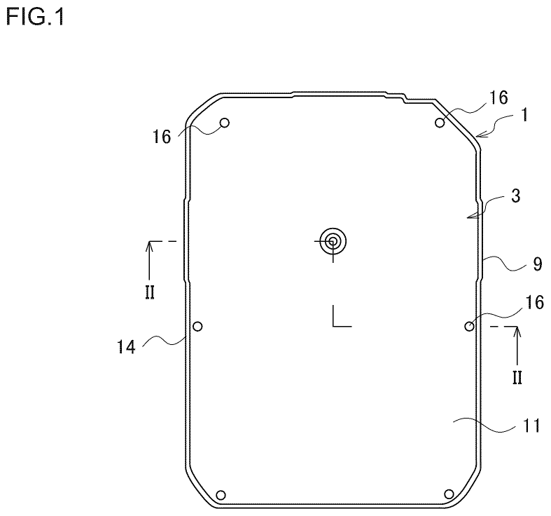

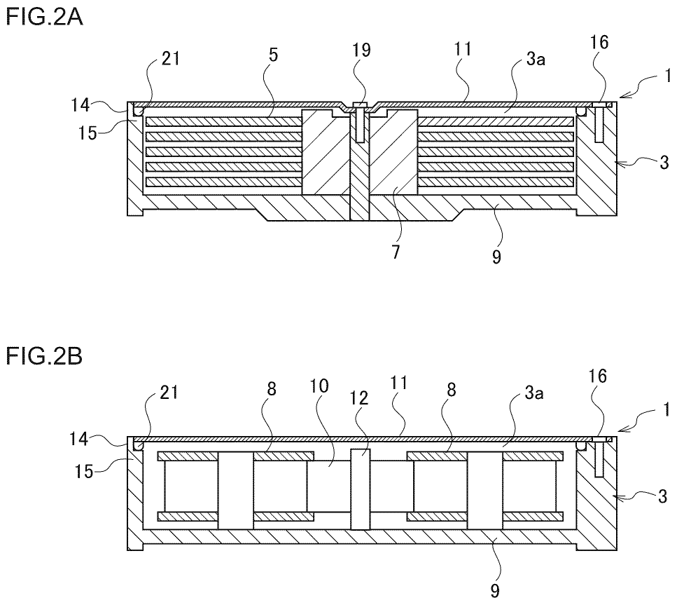

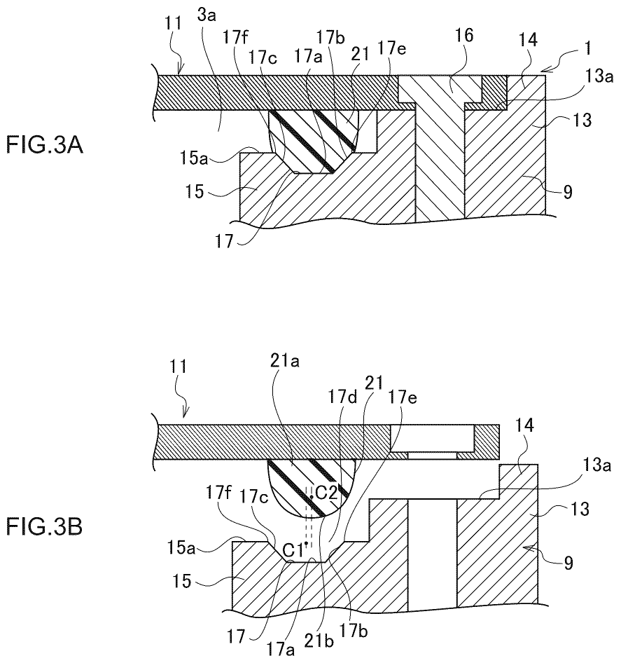

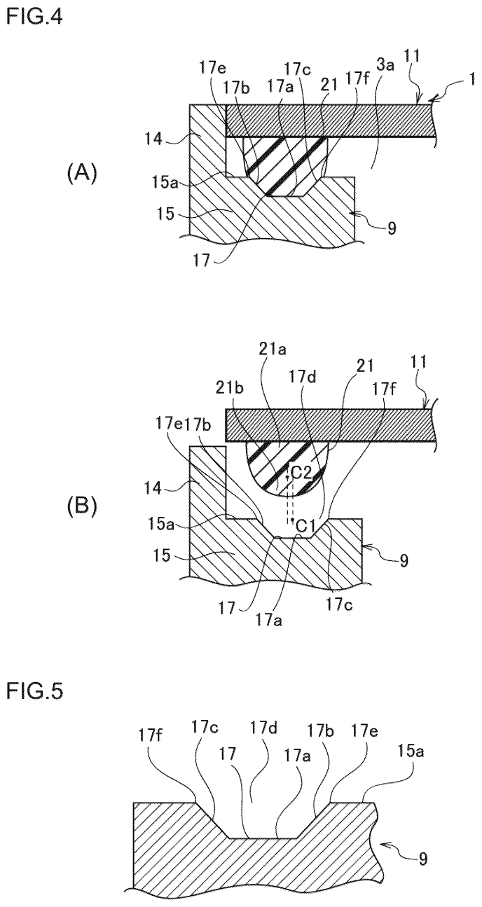

FIG. 1 is a plan view of a recording device according to the embodiment 1 of the present invention. FIG. 2A is a schematic sectional view taken along a line II-II of the recording device of FIG. 1, and FIG. 2B is a schematic sectional view according to a modification. FIG. 3A is a schematic sectional view crossing a fastener and illustrating the gasket and its periphery of FIG. 2 with enlargement, and FIG. 3B is a schematic sectional view illustrating a situation before attaching the cover of the same. FIG. 4A is a schematic sectional view not crossing the fastener and illustrating the gasket and its periphery of FIG. 1 with enlargement, and FIG. 4B is a schematic sectional view illustrating a situation before attaching the cover of the same. FIG. 5 is an enlarged sectional view of a recessed portion illustrated in FIG. 3.

The recording device 1 of the present embodiment 1 is a hard disk drive as a magnetic disk device, and accommodates disks 5 as recording media in a space 3a within a housing 3.

A plurality of the disks 5 are stacked in a thickness direction of the recording device 1 (hereinafter simply referred o as “thickness direction”), and are configured to be supported rotatably using a spindle motor 7. These disks 5 are configured so that information is read from and written through heads not shown.

It should be noted that the recording device 1 is not limited to the magnetic disk device and may be the other disk drive such as an optical disk device or the other recoding device. For example, the recoding device 1 may be a tape-embedded-type drive as illustrated in FIG. 2B. The recoding device 1 accommodates a tape film 10 as a recording medium wound between two tape reels 8 and a head assembly 12 for reading and writing of information in the housing 3.

The housing 3 comprises a base 9 and a cover 11, and is to close or seal inside. In addition, the housing 3 may be changed in shape to be applied to a device other than the recording device 1.

The base 9 is made of metal such as aluminum, and is formed into a box shape opening on one side in the thickness direction. The base 9 may, however, employ an appropriate shape as long as the base should be a box shape capable of accommodating the disks 5. The base 9 of the present embodiment is an approximate rectangular shape in a plan view, for example. In addition, the plan view means a state seen in the thickness direction and does not mean to distinguish a plan and a bottom.

The base 9 is closed by the cover 11 attached to the opening on the one side in the thickness direction. This seals the space 3a in the housing 3 accommodating the disks 5. Gas such as helium having resistance less than of air may be sealed in the sealed space 3a.

An opening edge of the base 9 is provided with a cover-receiving portion 13, a projected portion 14, and a gasket-receiving portion 15.

The cover-receiving portion 13 is formed so as to correspond to a portion at which the cover 11 is fastened to the base 9 as illustrated in FIGS. 3 and 4. According to the present embodiment, a plurality of the cover-receiving portions 13 are formed at intervals in a circumferential direction of the base 9. In addition, the cover-receiving portion 13 may be formed into a loop shape along an outer periphery of the base 9.

The cover-receiving portion 13 is protruded in the thickness direction of the base 9 and receives the cover 11 at a cover-receiving face 13a on a tip end in the thickness direction by putting the cover thereon in the thickness direction. This enables a space to be defined between the cover 11 and the base 9. In this state, the cover 11 is fastened to the cover-receiving portion 13 using a fastener 16 such as a bolt.

In the present embodiment, the cover-receiving face 13a of the cover-receiving portion 13 is configured by a flat face along a width direction intersecting the thickness direction. The width direction includes a direction orthogonal to the thickness direction and a direction slightly inclined to the direction orthogonal.

It should be noted that the cover-receiving face 13a of the cover-receiving portion 13 may not be necessarily the flat face as long as the cover-receiving face receives the cover 11 in the thickness direction. Further, the cover-receiving portion 13 may not be protruded in the thickness direction, and a projected portion or a bent portion projected in the thickness direction may be formed on the cover 11. Alternatively, the cover-receiving portion 13 is projected in the thickness direction and the projected portion or the bent portion may be formed on the cover 11.

The projected portion 14 is protruded from the cover-receiving portion 13 at a portion corresponding to the fastener 16 in the thickness direction. At a portion without the cover-receiving portion 13 other than the portion corresponding to the fastener 16, the projected portion 14 is protruded from the gasket-receiving portion 15 in the thickness direction. The projected portion 14 is formed in a continuous loop shape along the outer periphery of the base 9 in a whole of adjacent regions and un-adjacent regions of the fasteners 16. In addition, the projected portion 14 may be intermittently formed.

The gasket-receiving portion 15 receives the gasket 21 attached to the cover 11 to compress the gasket 21 between the gasket-receiving portion 15 and the cover 11 in the thickness direction. The gasket-receiving portion 15 of the present embodiment is formed into a loop shape along the outer periphery of the base 9 in the plan view.

The gasket-receiving portion 15 has a gasket-receiving face 15a oriented toward the cover 11 in the thickness direction. The gasket-receiving face 15a is formed flat along the width direction. With this gasket-receiving face 15a, the gasket 21 is received. It should be noted that the gasket-receiving face 15a may not be flat and may have irregularities or the like as long as the gasket-receiving face receives the gasket 21.

The gasket-receiving face 15a of the gasket-receiving portion 15 is provided with a recessed portion 17. The recessed portion 17 should be formed on the other against one of the base 9 and the cover 11 to which the gasket 21 is provided. Accordingly, if the gasket 21 is provided on the base 9, the recessed portion 17 may be provided on the cover 11.

The recessed portion 17 follows the gasket-receiving portion 15 and is provided into a loop shape in the plan view. It should be noted that, although the loop shape is a closed loop being entirely continuous in the present embodiment, it may be an open loop being partly discontinuous or a broken line shape being intermittent in view of a space or the like.

In a cross section spanning inside and outside the loop shape, part of the gasket 21 in a compressed state is entered into the recessed portion 17 in the thickness direction as the compressing direction. This prevents repulsive force of the gasket 21 from being raised. The recessed portion 17 of the present embodiment is filled with the entered gasket 21.

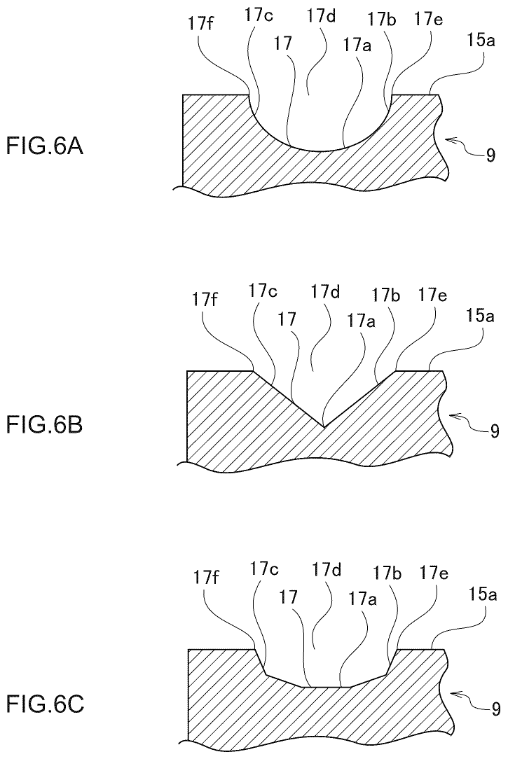

The sectional shape of the recessed portion 17 is a trapezoidal shape in the present embodiment. Namely, the recessed portion 17 is provided with a bottom face 17a, and side faces 17b and 17c as an inner face, and has a width gradually increasing from the bottom face 17a toward the opening 17d. It should be noted that the sectional shape of the recessed portion 17 is not limited to the trapezoidal shape, but may be the other geometric figure such as an arc shape, a V-shape, or a polygon as illustrated in FIGS. 6A-6C.

The bottom face 17a of the recessed portion 17 of the present embodiment is a flat face along the width direction, and forms a bottom portion of the recessed portion 17. It should be noted that the bottom face 17a may be inclined relatively to the width direction. In this case, the inclined bottom face 17a entirely forms the bottom portion. Accordingly, the bottom portion does not necessarily mean a bottom-most portion. In addition, the bottom face 17a may be a curved face or a waved face.

As illustrated in FIG. 6A, in a case of the sectional shape of the recessed portion 17 being entirely the arc shape, a region with a relatively low inclination may be a bottom portion. For example, in a case that the sectional shape is the simple arc shape, a region with a relatively low inclination relative to a portion as a boundary at which a width component is equivalent with a thickness component is the bottom portion. As illustrated in FIG. 6B, in a case that the sectional shape of the recessed portion 17 is the V-shape, a bottom-most portion is the bottom portion. As illustrated in FIG. 6C, in a case that the sectional shape of the recessed portion 17 is the polygon, not only a bottom face or a bottom-most portion but also a portion other than side faces may be entirely the bottom portion. In this case, the side faces may be faces adjoining to the gasket-receiving face 15a or the like.

The side faces 17b and 17c of the recessed portion 17 of the present embodiment is inclined faces and become gradually apart from each other in the width direction toward the opening 17d from both ends in the width direction of the bottom face 17a. Opening edges 17e and 17f are defined between the side faces 17b and 17c and the gasket-receiving face 15a of the gasket-receiving portion 15, respectively.

It should be noted that the side faces 17b and 17c are in line symmetry relative to a symmetry axis along the thickness direction. The side faces 17b and 17c are, however, not necessarily in line symmetry and may be inclined faces having different inclinations. Further, the side faces 17b and 17c are not necessarily the inclined faces and may be arc-shaped faces or the like as illustrated in FIG. 6.

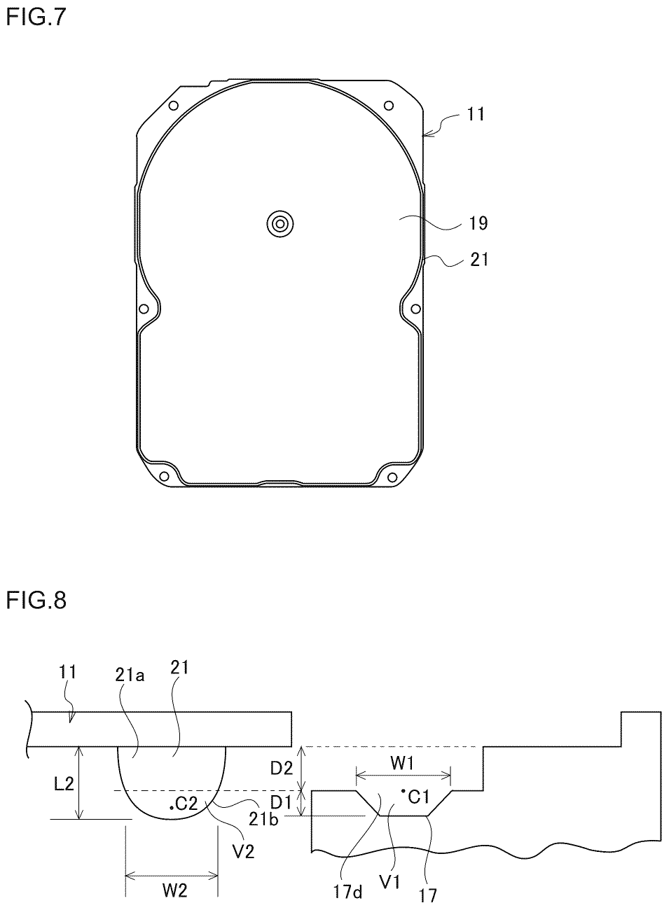

FIG. 7 is a bottom view of the cover 11. FIG. 8 is a conceptual view illustrating the gasket in a free state and the recessed portion 17 side by side.

The cover 11 is attached to the base 9 to close the space 3a of the housing 3 accommodating the disks 5 as illustrated in FIGS. 1-4, 7 and 8.

The cover 11 is made of metal such as aluminum and is formed into a plate shape to cover the opening of the base 9. The cover 11 of the present embodiment is in an approximate rectangular shape in the plan view. The shape of the cover 11 is, however, not limited to a particular shape as long as it covers the opening of the base 9.

The cover 11 is received at an outer peripheral edge thereof by the cover-receiving portion 13 of the base 9 in the thickness direction in a state that the cover covers the opening of the base 9. In this state, the cover 11 is fixed to the base 9 using fasteners 19 such as bolts. To the cover 11, the gasket 21 for sealing is attached. The gasket 21 is in contact with the base 9 so that the gasket is interposed between the base 9 and the cover 11 in the compressed state. It should be noted that the gasket 21 should be attached to one of the base 9 and the cover 11 and be in contact with the other of the base 9 and the cover 11, and the gasket may be attached to the base 9.

The gasket 21 in the compressed state seals between the cover 11 and the base 9. The gasket 21 of the present embodiment is compressed between the cover 11 and the gasket-receiving portion 15 of the base 9 to seal between the cover 11 and the gasket-receiving portion 15.

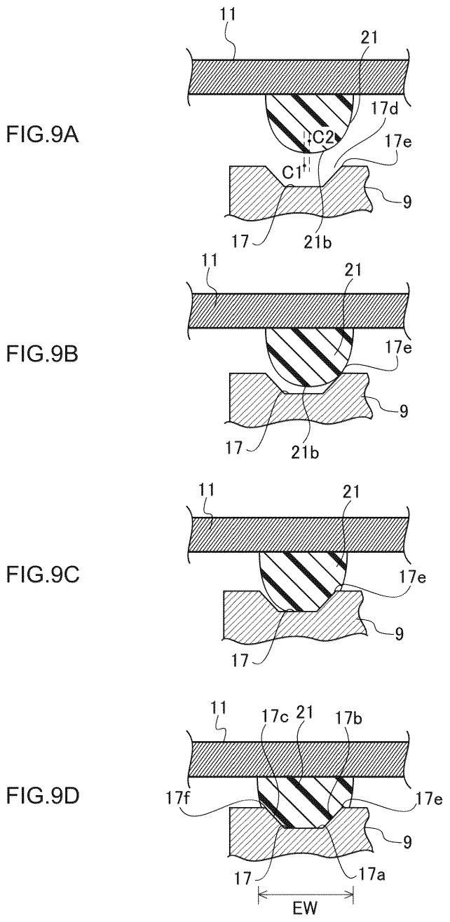

In particular, the gasket 21 bridges the recessed portion 17 in the width direction so as to be in contact with both the opening edges 17e and 17f and is compressed between the cover 11 and the base 9. With this, an effective width EW (see FIG. 9D) extending over the opening edges 17e and 17f is ensured.

The effective width EW is a width of the gasket 21. If the width is varied in the thickness direction, the effective width EW may be a width of a narrowest portion or a mean value of the width of the gasket 21 excepting a portion within the recessed portion 17.

Further, part of the compressed gasket 21 is entered into the recessed portion 17 between the opening edges 17e and 17f so as to be escaped. With this, the recessed portion 17 prevents the gasket 21 in the compressed state from being raised in repulsive force. The part of the gasket 21 within the recessed portion 17 fills the inside of the recessed portion 17 and is in contact with the bottom face 17a and the side faces 17b and 17c being the inner face of the recessed portion 17.

It should be noted that the gasket 21 should be interposed between the cover 11 and the base 9 in the compressed state to seal the housing 3, and may be appropriate one such as liquid gasket or molded gasket. In the case of the liquid gasket, it is applied to and cured on the cover 11 in advance. In the case of the molded gasket, it is adhered to the cover 11 in advance.

The gasket 21 of the present embodiment entirely has an arc-shaped cross section in a free state without compression. With this, the gasket 21 in the free state is gradually reduced in width from a base end to a tip end in the thickness direction. In the compressed state, a part of the gasket 21 positioned between the cover 11 and the base 9 exhibits a barrel shape. It should be noted that the arc-shaped cross section is a cross section, a surface of which is an arc shape. The cross section in this context is a cross section spanning inside and outside the loop shape.

Further, the gasket 21 in the free state has a dimension L2 in the thickness direction that is greater than a sum of a depth D1 of the recessed portion 17 and a distance D2 between the cover 11 and the opening 17d of the recessed portion 17 in the closed state. It should be noted that the dimension L2 of the gasket 21 in the thickness direction may be smaller than the sum of the depth D1 of the recessed portion 17 and the distance D2 between the cover 11 and the opening 17d of the recessed portion 17 in the closed state.

The gasket 21 is provided with a tip end portion 21b relative to a body portion 21a in the free state. Namely, since the gasket 21 entirely has the arc-shaped cross section, an end opposite to the cover 11 in the thickness direction forms the tip end portion 21b with the arc-shaped cross section.

The tip end portion 21b is a region coming into contact with one opening edge 17e prior to the other portion when compressing the gasket 21. The tip end portion 21b in the free state just before compression has, in the width direction, a center C2 that is deviated from a center C1 of the opening 17d of the recessed portion 17. The gasket 21 is, therefore, compressed in a state that the center C2 of the tip end portion 21b in the free state is deviated from the center C1 of the opening 17d of the recessed portion 17.

The deviation includes slight deviation. With the deviation, the tip end portion 21b of the gasket 21 antecedently comes into contact with the one opening edge 17e at the time of the compression so as not to simultaneously come into contact with both the opening edges 17e and 17f.

Accordingly, the present embodiment discharges gas of the inside the recessed portion 17 until the tip end portion 21b comes into contact with the other opening edge 17f after coming into contact with the one opening edge 17e at the time of the compression of the gasket 21, to more surely prevent the gasket 21 from raising in repulsive force. In addition, the gas is not only air but also gas according to surroundings at the time of the sealing.

Further, the present embodiment fills the inside of the recessed portion 17 with the gasket 21 while discharging the gas of the inside the recessed portion 17. Accordingly, adhesion of the gasket 21 to the recessed portion 17 is improved and residual of the gas in the recessed portion 17 is suppressed to more surely prevent the repulsive force from raising.

It should be noted that the center C2 of the tip end portion 21b in the width direction may be a center of a mean value of the width, a center of a maximum width or the like of the tip end portion 21b. Further, the center C2 of the tip end portion 21b may match the center C1 of the recessed portion 17 in the width direction at part of the loop shape.

According to the present embodiment, the gasket 21 has a corresponding width W2 corresponding to a width W1 of the opening 17d of the recessed portion 17 in the free state, the corresponding width being the same as the width W1 of the opening 17d of the recessed portion 17. The corresponding width W2 in the gasket 21 in the free state is a width at an apart position apart from the cover 11 by the distance D2 from the cover 11 to the opening 17d of the recessed portion 17 in the closed state.

A volume V2 of the gasket 21 in the free state on the tip end side from the apart position in the thickness direction is greater than a volumetric capacity V1 of the recessed portion 17. With this, the gasket 21 in the compressed state fills the inside of the recessed portion 17.

FIGS. 9A-D are schematic sectional views illustrating manufacturing process for the recording device 1 of the embodiment 1.

In manufacturing of the recording device 1 of the present embodiment, the cover 11 is attached to the base 9 of the housing 3 accommodating the disks 5, to close the space 3a of the hosing 3 accommodating the disks 5.

Namely, the cover 11 to which the gasket 21 is attached faces the base 9 in the thickness direction. At this time, the center C2 of the tip end portion 21b of the gasket 21 in the width direction is deviated from the center C1 of the opening 17d of the recessed portion 17 in the width direction according to the positioning between the cover 11 and the base 9.

In this state, the cover 11 and the base 9 approach each other and the tip end portion 21b of the gasket 21 is brought into contact with the one opening edge 17e of the recessed portion 17 of the base 9. In addition, if the deviation is reversely set between the center C2 of the tip end portion 21b of the gasket 21 in the width direction and the center C1 of the opening 17d of the recessed portion 17 in the width direction, the tip end portion results in contact with the opening edge 17f.

Approaching the cover 11 and the base 9 further, the gasket 21 is compressed between the cover 11 and the opening edge 17e of the base 9 to swell in the width direction.

Then, the gasket 21 swells at part facing the recessed portion 17 in the thickness direction so as to be escaped into the recessed portion 17 and is prevented from raising in repulsive force. At this time, the gas of the inside of the recessed portion 17 is discharged between the other opening edge 17f of the recessed portion 17 and the tip end portion 21b. Thus, raising in repulsive force of the gasket 21 due to the residual of the gas in the recessed portion 17 is suppressed and the adhesion of the gasket 21 to the recessed portion 17 is improved.

Thereafter, in a state that the cover 11 is received by the cover-receiving face 13a of the cover-receiving portion 13 of the base 9 according to the approaching of the cover 11 and the base 9, the recessed portion 17 is completely filled with the gasket 21 and the gasket 21 is in contact with the bottom face 17a, the side faces 17b and 17c, and the other opening edge 17f of the recessed portion 17.

In this way, the present embodiment increases the effective width EW to improve sealability while preventing the gasket 21 from raising in repulsive force.

In this state, the cover 11 is fixed to the base 9 using the fasteners 16 and 19 to complete the manufacturing of the recording device 1.

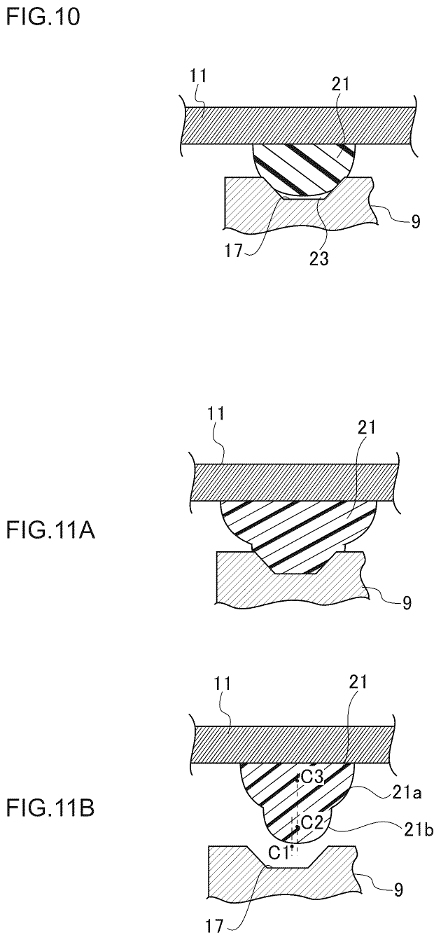

FIGS. 10-12 are schematic sectional views illustrating gaskets according to modifications and their periphery with enlargement.

The modification of FIG. 10 makes the volume V2 (see FIG. 8) of the gasket 21 on the tip end side relative to the apart position smaller than the volumetric capacity V1 (see FIG. 8) of the recessed portion 17. With this, the gasket 21 in the compressed state does not fill the recessed portion 17 and defines a void portion 23 in the recessed portion 17.

In addition, a percentage of the volume V2 of the gasket 21 relative to the volumetric capacity V1 of the recessed portion 17 is preferably 50% or more in view of the repulsive force of the gasket 21.

The gas corresponding to the volume of the gasket 21 occupying the inside of the recessed portion 17 is discharged at the time of the compression of the gasket 21. Accordingly, the gas in the void portion 23 is little compressed. Accordingly, even if the void portion 23 is formed, raising of the repulsive force of the gasket 21 is suppressed.

The modification of FIG. 11 forms the gasket 21 as a multistage type. Namely, in the gasket 21, the body portion 21a and the tip end portion 21b have arc-shaped cross sections with different curvatures, respectively. The width of the body portion 21a is greater than the width of the tip end portion 21b. A center C3 of the body portion 21a in the width direction and the center C2 of the tip end portion 21b in the width direction are arranged coaxially.

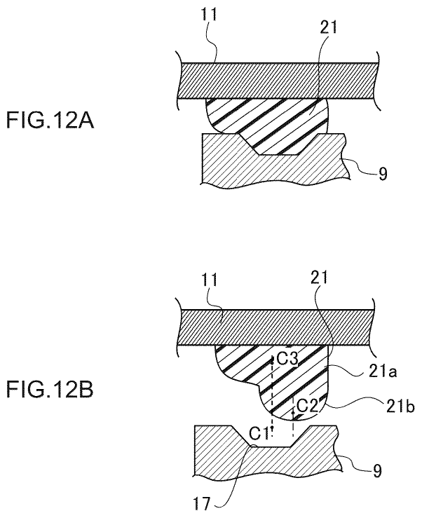

The modification of FIG. 12 deviates the center C3 of the body portion 21a in the width direction and the center C2 of the tip end portion 21b in the width direction based on the multistage type gasket 21 of FIG. 11. In this case, the center C3 of the body portion 21a of the gasket 21 in the free state just before compression may match the center C1 of the recessed portion 17 in the width direction.

In addition, although the gasket 21 has two stages in the modifications of FIGS. 11 and 12, the gasket 21 may have three or four stages or the like.

Even these modifications provide the same effect as the embodiment 1.

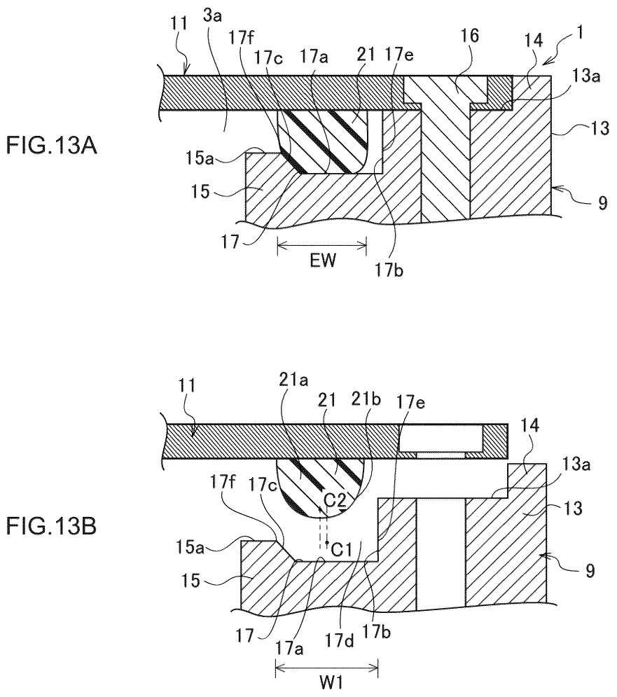

FIG. 13A is a schematic sectional view crossing a fastener and illustrating a gasket according to the embodiment 2 of the present invention and its periphery with enlargement, and FIG. 13B is a schematic sectional view illustrating a situation before attaching the cover of the same. In addition, the embodiment 2 is common with the embodiment 1 in the basic structure and corresponding components are represented with the same reference numerals to eliminate duplicate explanation.

In the present embodiment, a shape of the recessed portion 17 is changed by comparison with the embodiment 1. The others are the same as of the embodiment 1.

Namely, a recessed portion 17 of the present embodiment has a side face 17b located outside in the width direction and configured by a wall face of a cover-receiving portion 13 at a portion corresponding to a fastener 16. The side face 17b is along the thickness direction. The recessed portion 17 is extended to the cover-receiving portion 13 in the width direction and a width W1 of an opening 17d is greater than of the embodiment 1. In addition, at a portion other than the portion corresponding to the fastener 16, the side face 17b may be configured by a wall face of a projected portion 14.

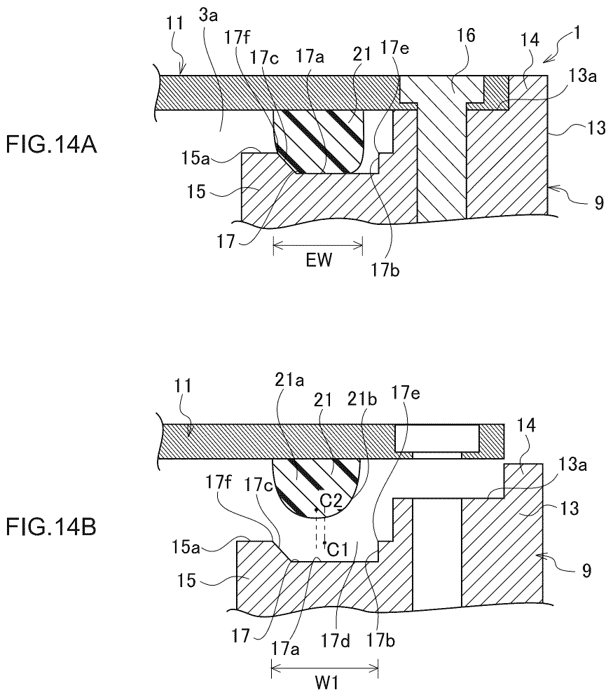

In addition, the side face 17b may be a face being simply along the thickness direction as illustrated in FIG. 14 without using the wall face of the cover-receiving portion 13.

The present embodiment brings a tip end portion 21b of a gasket 21 into contact with only one opening edge 17f located inside in the width direction in the recessed portion 17 in opening edges 17e and 17f of the recessed portion 17. Compression is conducted in this state, and the gasket 21 is entirely led by means of a side face 17c of the recessed portion 17 toward the side face 17b on the outside in the width direction. As this result, part of the gasket 21 located in the recessed portion 17 swells outward in the width direction by comparison with the free state and an effective width EW is increased while suppressing raising of repulsive force.

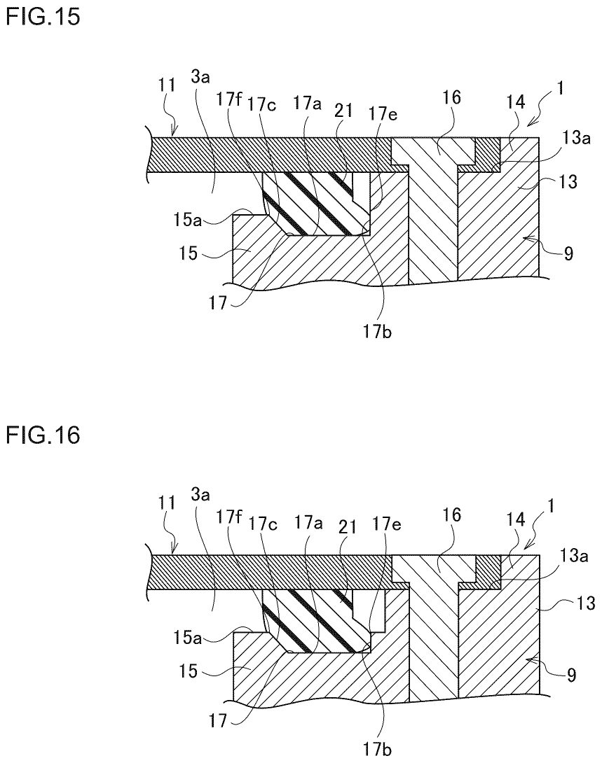

FIG. 15 and FIG. 16 are schematic sectional views illustrating a gasket 21 of a recording device 1 according to modifications and their peripheries with enlargement.

The modifications of FIG. 15 and FIG. 16 increase in swelled amount of a part of the gaskets 21 located in the recessed portion 17 by comparison with the embodiment and the modification of FIG. 13 and FIG. 14.

With this, in the modifications of FIG. 15 and FIG. 16, the part of the gasket 21 located inside the recessed portion 17 is protruded outward from a part of the gasket located outside the recessed portion 17 in the width direction and is in contact with the side face 17b in the width direction.

The embodiment 2 and the modifications provide the same effect as the embodiment 1.

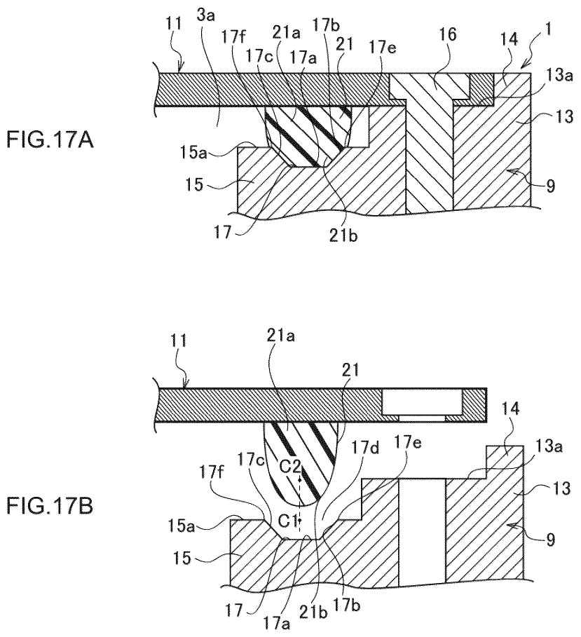

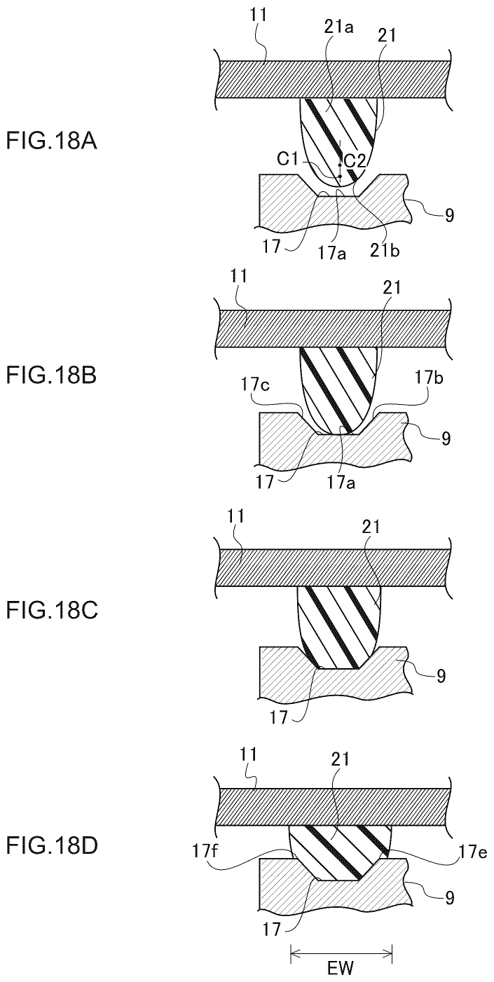

FIG. 17 are schematic sectional views illustrating a gasket of a recording device according to the embodiment 3 of the present invention and its periphery with enlargement. FIGS. 18A-D are schematic sectional views illustrating manufacturing process for the recording device of the embodiment 3. In addition, the embodiment 3 is common with the embodiment 1 in the basic structure and corresponding components are represented with the same reference numerals to eliminate duplicate explanation.

In the present embodiment, when a cover 11 and a base 9 face each other at the time of manufacturing, a tip end portion 21b of a gasket 21 is brought into contact with an inner face of a recessed portion 17.

The gasket 21 of the present embodiment in the free state has a corresponding width W2 (see FIG. 8) being narrower than a width W1 (see FIG. 8) of an opening 17d of the recessed portion 17 and entirely has a parabola-shaped cross section. A dimension L2 (see FIG. 8) of the gasket 21 in the thickness direction is the same as or greater than a sum of a depth D1 (see FIG. 8) of the recessed portion 17 and a distance D2 (see FIG. 8) between the cover 11 and the opening 17d of the recessed portion 17 in the closed state. Further, a volume V2 (see FIG. 8) on a tip end side of the gasket 21 in the free state from an apart position in the thickness direction is greater than a volumetric capacity V1 (seen FIG. 8) of the recessed portion 17.

When manufacturing the recording device 1, as illustrated in FIGS. 18, the cover 11 and the base 9 face each other and the tip end portion 21b of the gasket 21 provided on the cover 11 is brought into contact with the bottom face 17a as the inner face of the recessed portion 17 provided on the base 9.

At this time, a center C2 of the tip end portion 21b in the width direction is arranged coaxially with a center C1 of the opening 17d of the recessed portion 17 in the width direction. The center C2 of the tip end portion 21b in the width direction may be, however, deviated from the C1 of the opening 17d of the recessed portion 17 in the width direction. In this case, the tip end portion 21b of the gasket 21 may be brought into contact with the side faces 17b and 17c as an inner face of the recessed portion 17 according to a deviating amount between the centers C1 and C2.

Next, the cover 11 and the base 9 are approached to each other to compress the gasket 21. With this, part of the gasket 21 swells in the width direction in a state that the part of the gasket is entered into the recessed portion 17 in the compressing direction. Advancing the swelling, an inside of the recessed portion 17 is filled with the gasket 21 while gas is discharged around the gasket 21. It, therefore, prevents raising of the repulsive force caused by residual of the gas in the recessed portion 17.

In a state that the recessed portion 17 is filled with the gasket 21, the gasket 21 is in contact with the opening edges 17e and 17f of the recessed portion 17 in the width direction. It should be noted that the gasket 21 may be in contact with one of the opening edges 17e and 17f only.

The gasket 21 is, therefore, compressed between the cover 11 and the base 9 similarly to the embodiment 1 and swells in the width direction to increase the effective width EW. Further, the part of the gasket 21 is entered into the recessed portion 17, thereby suppressing raising of the repulsive force of the gasket 21.

The present embodiment, therefore, increases the effective width EW to improve sealability while preventing the gasket 21 from raising in repulsive force.

1. A recording device, comprising:
a base for a housing accommodating a recording medium;
a cover attached to the base to close a space of the housing accommodating the recording medium;
a gasket attached to one of the base and the cover and being in contact with the other of the base and the cover so as to be interposed between the base and the cover in a compressed state; and
a recessed portion provided on said other of the base and the cover so that part of the gasket in the compressed state is entered into the recessed portion in a compressing direction, wherein
the gasket is provided with a tip end portion having an arc-shaped cross section in a free state, is compressed in a state that a center of the tip end portion in the free state is deviated from a center of an opening of the recessed portion in a width direction intersecting the compressing direction, and is in contact with at least one of opening edges in the width direction of the recessed portion and an inner face of the recessed portion in the compressed state.

2. The recording device according to claim 1, wherein
the gasket is in contact with both the opening edges in the width direction of the recessed portion.

3. The recording device according to claim 1, wherein
the gasket is in contact with a bottom portion of the inner face of the recessed portion.

4. The recording device according to claim 1, wherein
an inside of the recessed portion is filled with the entered gasket.

5. A manufacturing method for a recording device that attaches a cover to a base for a housing accommodating a recording medium to close a space of the housing accommodating the recording medium, comprising:
facing the cover and the base mutually and bringing a tip end portion of a gasket provided on one of the cover and the base into contact with an inner face of a recessed portion provided on the other of the cover and the base; and
approaching the cover and the base to each other to compress the gasket, thereby swelling part of the gasket in a width direction intersecting a compressing direction while said part of the gasket in a compressed state is entered into the recessed portion in the compressing direction and bringing the gasket into contact with at least one of opening edges in the width direction of the recessed portion to conduct the closing.

6. The manufacturing method for a recording device according to claim 5, wherein
the tip end portion of the gasket comes into contact with a bottom portion of the recessed portion at the time of the facing of the cover and the base.

7. The manufacturing method for a recording device according to claim 6, wherein
the gasket comes into contact with both the opening edges in the width direction of the recessed portion at the time of the closing.

8. The manufacturing method for a recording device according to claim 5, wherein
an inside of the recessed portion is filled with the entered gasket.

9. The manufacturing method of a recording device according to claim 5, wherein
a width of an opening of the recessed portion is greater than a corresponding width of the gasket in the free state, and
the corresponding width is a width in the gasket in the free state at an apart position apart from said one of the base and the cover by a distance, the distance being from said one of the base and the cover to the opening of the recessed portion in the closed state.

10. The manufacturing method of a recording device according to claim 9, wherein
a volume of the gasket on a tip end side from the apart position in the compressing direction in the free state is greater than a volumetric capacity of the recessed portion.

11. A housing comprising:
a base and a cover attached to the base;
a gasket attached to one of the base and the cover and being in contact with the other of the base and the cover so as to be interposed between the base and the cover in a compressed state; and
a recessed portion provided on said other of the base and the cover so that part of the gasket in the compressed state is entered into the recessed portion in a compressing direction, wherein
the gasket is provided with a tip end portion having an arc-shaped cross section in a free state, is compressed in a state that a center of the tip end portion in the free state is deviated from a center of an opening of the recessed portion in a width direction intersecting the compressing direction, and is in contact with at least one of opening edges in the width direction of the recessed portion and an inner face of the recessed portion in the compressed state.
